(19) United States
(12) Patent Application Publication
(10) Pub. No.: US 2018/0114941 A1
(43) Pub. Date: Apr. 26, 2018

(54) OLED DEVICE AND OLED DISPLAY DEVICE

(71) Applicants: BOE TECHNOLOGY GROUP CO., LTD., Beijing (CN); CHENGDU BOE OPTOELECTRONICS TECHNOLOGY CO., LTD., Chengdu (CN)

(72) Inventors: Dong CHEN, Beijing (CN); Yinan LIANG, Beijing (CN); Kening ZHENG, Beijing (CN)

(21) Appl. No.: 15/719,012

(22) Filed: Sep. 28, 2017

(30) Foreign Application Priority Data
Oct. 21, 2016 (CN) 201610922146.0

(51) Int. Cl. H01L 51/50

(52) U.S. Cl. CPC H01L 51/5088; H01L 51/5056; H01L 51/5024; H01L 51/5092; H01L 51/5096; H01L 51/5072

(57) ABSTRACT

An OLED device comprises an anode, a hole transport layer, an electro-luminescence layer, an electron transport layer and a cathode, which are superposed successively. A hole-side exciton utilization layer for allowing holes to freely pass therethrough is provided between the hole transport layer and the electro-luminescence layer, and/or an electron-side exciton utilization layer for allowing electrons to freely pass therethrough is provided between the electron transport layer and the electro-luminescence layer. Hole-side electro-luminescence material is doped in the hole-side exciton utilization layer, and the energy level of the hole-side electro-luminescence material is lower than that of material of the hole transport layer. Electron-side electro-luminescence material is doped in the electron-side exciton utilization layer, and the energy level of the electron-side electro-luminescence material is lower than that of material of the electron transport layer.

### CROSS REFERENCE TO RELATED APPLICATIONS

This application claims a priority of Chinese patent application No. 201610922146.0 filed with the Chinese patent office on Oct. 21, 2016 tiled as “OLED device and an OLED display device”, which is incorporated into this application as a whole by reference.

### FIELD OF TECHNOLOGY

The present disclosure relates to the technical field of display, and in particular to an OLED device and an OLED display device.

### BACKGROUND

Due to advantages of self-luminescence, rich color, quick response speed, wide angle of view, light weight, small thickness, low power consumption, capability of flexible display and the like, organic Light Emitting Diode (OLED) devices (also referred to as organic electro-luminescence diode devices) have attracted extensive attention. And OLED display devices made of OLED devices are regarded as display devices having a promising application prospect.

### SUMMARY

A first aspect of the present disclosure provides an OLED device, including an anode, a hole transport layer, an electro-luminescence layer, an electron transport layer and a cathode, which are superposed successively, wherein a hole-side exciton utilization layer for allowing holes to freely pass therethrough is provided between the hole transport layer and the electro-luminescence layer, and an electron-side exciton utilization layer for allowing electrons to freely pass therethrough is provided between the electron transport layer and the electro-luminescence layer; hole-side electro-luminescence material is doped in the hole-side exciton utilization layer, and the energy level of the hole-side electro-luminescence material is lower than that of material of the hole transport layer; and electron-side electro-luminescence material is doped in the electron-side exciton utilization layer, and the energy level of the electron-side electro-luminescence material is lower than that of material of the electron transport layer.

Optionally, in the hole-side exciton utilization layer, the doping concentration of the hole-side electro-luminescence material is about 0.5 wt % to 1 wt %; and in the electron-side exciton utilization layer, the doping concentration of the electron-side electro-luminescence material is about 0.5 wt % to 1 wt %.

Optionally, a distance between a surface of the hole-side exciton utilization layer facing the electro-luminescence layer and a surface of the electro-luminescence layer facing the hole-side exciton utilization layer is about 0 nm to 5 nm; and a distance between a surface of the electron-side exciton utilization layer facing the electro-luminescence layer and a surface of the electro-luminescence layer facing the electron-side exciton utilization layer is about 0 nm to 5 nm.

Optionally, the thickness of the hole-side exciton utilization layer is about 3 nm to 5 nm, and the thickness of the electron-side excitation utilization layer is about 3 nm to 5 nm.

Optionally, the OLED device further comprises an auxiliary hole transport layer for facilitating transportation of holes to the electro-luminescence layer, and the auxiliary hole transport layer is located between the hole-side exciton utilization layer and the electro-luminescence layer; and the OLED device further comprises an auxiliary electron transport layer for facilitating transportation of electrons to the electro-luminescence layer, and the auxiliary electron transport layer is located between the electron-side exciton utilization layer and the electro-luminescence layer.

Optionally, the OLED device further comprises an electron barrier layer which is located between the hole-side exciton utilization layer and the electro-luminescence layer or located between the hole transport layer and the hole-side exciton utilization layer, and the energy level of the hole-side electro-luminescence material is lower than that of material of the electron barrier layer; and the OLED device further comprises a hole barrier layer which is located between the electron-side exciton utilization layer and the electro-luminescence layer or located between the electron transport layer and the hole-side exciton utilization layer, and the energy level of the electron-side electro-luminescence material is lower than that of material of the hole barrier layer.

Optionally, the hole-side exciton utilization layer comprises hole-side host material in which the hole-side electro-luminescence material is doped, and the hole-side host material is the same as material of the electron barrier layer; and the electron-side exciton utilization layer comprises electron-side host material in which the electron-side electro-luminescence material is doped, and the electron-side host material is the same as material of the hole barrier layer.

Optionally, the hole-side exciton utilization layer comprises hole-side host material in which the hole-side electro-luminescence material is doped, and the hole-side host material is the same as material of the hole transport layer; and the electron-side exciton utilization layer comprises electron-side host material in which the electron-side electro-luminescence material is doped, and the electron-side host material is the same as material of the electron transport layer.

Optionally, the hole-side electro-luminescence material is the same or different with material of the electro-luminescence layer, and the electron-side electro-luminescence material is the same or different with material of the electro-luminescence layer.

A second aspect of the present disclosure provides an OLED display device, including the OLED device described in the above technical solution.

A third aspect of the present disclosure provides an OLED device, including an anode, a hole transport layer, an electro-luminescence layer, an electron transport layer and a cathode, which are superposed successively, wherein a hole-side exciton utilization layer for allowing holes to freely pass therethrough is provided between the hole transport layer and the electro-luminescence layer, or an electron-side exciton utilization layer for allowing electrons to freely pass therethrough is provided between the electron transport layer and the electro-luminescence layer; hole-side electro-luminescence material is doped in the hole-side exciton utilization layer, and the energy level of the hole-side electro-luminescence material is lower than that of material of the hole transport layer; and electron-side electro-luminescence material is doped in the electron-side exciton utilization layer, and the energy level of the electron-side electro-luminescence material is lower than that of material of the electron transport layer.

Optionally, in the hole-side exciton utilization layer, the doping concentration of the hole-side electro-luminescence material is about 0.5 wt % to 1 wt %; and in the electron-side exciton utilization layer, the doping concentration of the electron-side electro-luminescence material is about 0.5 wt % to 1 wt %.

Optionally, a distance between a surface of the hole-side exciton utilization layer facing the electro-luminescence layer and a surface of the electro-luminescence layer facing the hole-side exciton utilization layer is about 0 nm to 5 nm; and a distance between a surface of the electron-side exciton utilization layer facing the electro-luminescence layer and a surface of the electro-luminescence layer facing the electron-side exciton utilization layer is about 0 nm to 5 nm.

Optionally, the thickness of the hole-side exciton utilization layer is about 3 nm to 5 nm, and the thickness of the electron-side excitation utilization layer is about 3 nm to 5 nm.

Optionally, the OLED device further comprises an auxiliary hole transport layer for facilitating transportation of holes to the electro-luminescence layer, and the auxiliary hole transport layer is located between the hole-side exciton utilization layer and the electro-luminescence layer; and the OLED device further comprises an auxiliary electron transport layer for facilitating transportation of electrons to the electro-luminescence layer, and the auxiliary electron transport layer is located between the electron-side exciton utilization layer and the electro-luminescence layer.

Optionally, the OLED device further comprises an electron barrier layer which is located between the hole-side exciton utilization layer and the electro-luminescence layer or located between the hole transport layer and the hole-side exciton utilization layer, and the energy level of the hole-side electro-luminescence material is lower than that of material of the electron barrier layer; and the OLED device further comprises a hole barrier layer which is located between the electron-side exciton utilization layer and the electro-luminescence layer or located between the electron transport layer and the hole-side exciton utilization layer, and the energy level of the electron-side electro-luminescence material is lower than that of material of the hole barrier layer.

Optionally, the hole-side exciton utilization layer comprises hole-side host material in which the hole-side electro-luminescence material is doped, and the hole-side host material is the same as material of the electron barrier layer; and the electron-side exciton utilization layer comprises electron-side host material in which the electron-side electro-luminescence material is doped, and the electron-side host material is the same as material of the hole barrier layer.

Optionally, the hole-side exciton utilization layer comprises hole-side host material in which the hole-side electro-luminescence material is doped, and the hole-side host material is the same as material of the hole transport layer; and the electron-side exciton utilization layer comprises electron-side host material in which the electron-side electro-luminescence material is doped, and the electron-side host material is the same as material of the electron transport layer.

Optionally, the hole-side electro-luminescence material is the same or different with material of the electro-luminescence layer, and the electron-side electro-luminescence material is the same or different with material of the electro-luminescence layer.20.

A fourth aspect of the present disclosure provides an OLED display device, including the OLED device described in the above technical solution.

### BRIEF DESCRIPTION OF THE DRAWINGS

The accompanying drawings described herein are used for providing further understanding of the present disclosure and constitute a part of the present disclosure. Illustrative embodiments of the present disclosure and descriptions thereof are used for explaining the present disclosure and not intended to form any inappropriate limitations to the present disclosure, in which:

FIG. 1 is a structure diagram of an OLED device;

FIG. 2 is a schematic view of the working principle of the OLED device in FIG. 1;

FIG. 3 is a structure diagram of an OLED device according to an embodiment of the present disclosure;

FIG. 4 is a schematic view of the working principle of the OLED device of FIG. 3;

FIG. 5 is a structure diagram of the OLED device according to another embodiment of the present disclosure;

FIG. 6 is a structure diagram of the OLED device according to yet another embodiment of the present disclosure;

FIG. 7 shows an arrangement mode of a hole-side exciton utilization layer and an electron-side exciton utilization layer of FIG. 6;

FIG. 8 shows another arrangement mode of the hole-side exciton utilization layer and the electron-side exciton utilization layer of FIG. 6; And

FIG. 9 is an OLED display device provided by an embodiment of this disclosure.

### REFERENCE NUMERALS

1: substrate;
2: anode;
3: hole transport layer;
4: hole-side exciton utilization layer;
5: auxiliary hole transport layer;
6: electron barrier layer;
7: electron-luminescence layer;
8: hole barrier layer;
9: auxiliary electron transport layer;
10: electron-side exciton utilization layer;
11: electron transport layer;
12: cathode;
100: display device;
a: hole;
b: electron; and
c: exciton.

### DETAILED DESCRIPTION

To further describe the OLED device and OLED display device provided by the embodiments of the present disclosure, the detailed description will be given below with reference to the drawings of the specification.

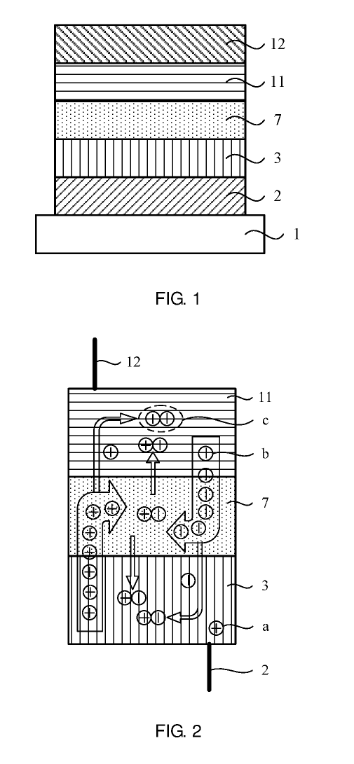

Referring to FIG. 1, the basic structure of an OLED device is generally a sandwich structure consisting of an anode 2, a cathode 12 and functional layers located between the anode 2 and the cathode 12, wherein the functional layers generally include a Hole Transport Layer (HTL) 3, an Electro-Luminescence layer (EL) 7, an Electron Transport Layer 11 (ETL) and the like. When a voltage is applied to the OLED device, holes a output from the anode 2 and electrons b output from the cathode 12 are combined in the EL 7, so that the material of the EL 7 is excited to emit light.

During the operation of the OLED device, referring to FIG. 2, excitons c formed by the holes a and the electrons b both transported to the EL 7 and then combined therein may move to a transport layer (e.g., the HTL 3 or the ETL 11); or, the electrons b transported to the EL 7 may move to the HTL 3, and may be then combined with the holes a in the HTL 3 to form excitons c; or, the holes a transported to the EL 7 may move to the ETL 11, and may be then combined with the electrons b in the ETL 11 to form excitons c. However, the excitons c present in a transport layer may be insufficient to excite the material of this transport layer to emit light. Therefore, the excitons c present in this transport layer may be deactivated in a non-radiative transition heat transfer manner, and consequently, the temperature within the OLED device rises so that the aging of the OLED device is quickened and the service life of the OLED device is thus shortened.

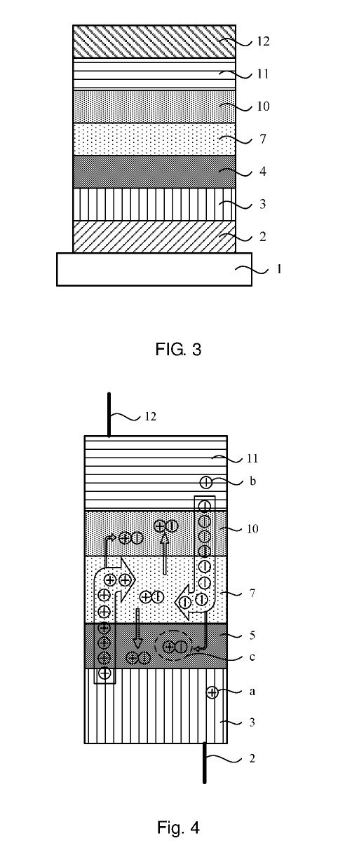

Referring to FIG. 3 and FIG. 4, the embodiments of the present disclosure provide an OLED device, including an anode 2, a hole transport layer 3, an electro-luminescence layer 7, an electron transport layer 11 and a cathode 12, which are superposed successively. A hole-side exciton utilization layer 4 for allowing holes a to freely pass therethrough is provided between the hole transport layer 3 and the electro-luminescence layer 7, and/or an electron-side exciton utilization layer 10 for allowing electrons b to freely pass therethrough is provided between the electron transport layer 11 and the electro-luminescence layer 7. Hole-side electro-luminescence material is doped in the hole-side exciton utilization layer 4, and the energy level of the hole-side electro-luminescence material is lower than that of material of the hole transport layer 3. Electron-side electro-luminescence material is doped in the electron-side exciton utilization layer 10, and the energy level of the electron-side electro-luminescence material is lower than that of material of the electron transport layer 11.

Illustratively, the OLED device provided by the embodiments of the present disclosure includes not only a substrate 1, and an anode 2, a hole transport layer 3, an electro-luminescence layer 7, an electron transport layer 11 and a cathode 12 which are successively superposed on the substrate 1, but also the hole-side exciton utilization layer 4, or the electron-side exciton utilization layer 10 only, or both the hole-side exciton utilization layer 4 and the electron-side exciton utilization layer 10. The following detailed description will be given by taking the OLED device including both the hole-side exciton utilization layer 4 and the electron-side exciton utilization layer 10 as example.

Referring to FIGS. 3 and 4, during the operation of the OLED device, holes a move from the anode 2 towards the electro-luminescence layer 7, and electrons b move from the cathode 12 towards the electro-luminescence layer 7. The holes a and the electrons b moving to the electro-luminescence layer 7 are combined to form excitons c. The excitons c excite the material of the electro-luminescence layer 7 so that the electro-luminescence layer 7 emits light. Part of the excitons c formed in the electro-luminescence layer 7 will move towards the transport layers (the hole transport layer 3 and the electron transport layer 11). For example, when part of the excitons c formed in the electro-luminescence layer 7 move towards the hole transport layer 3, the excitons c will pass through the hole-side exciton utilization layer 4, and the hole-side exciton utilization layer 4 captures the excitons c. Since the energy level of the hole-side electro-luminescence material in the hole-side exciton utilization layer 4 is lower than that of the material of the hole transport layer 3, the excitons c can excite the hole-side electro-luminescence material in the hole-side exciton utilization layer 4 so that the hole-side electro-luminescence material emits light. In this way, the number of excitons c moving to the hole transport layer 3 is decreased. Similarly, when part of the excitons formed in the electro-luminescence layer 7 move towards the electron transport layer 11, the excitons c will pass through the electron-side exciton utilization layer 10, and the electron-side exciton utilization layer 10 captures the excitons c. Since the energy level of the electron-side electro-luminescence material in the electron-side exciton utilization layer 10 is lower than that of the material of the electron transport layer 11, the excitons c can excite the electron-side electro-luminescence material in the electron-side exciton utilization layer 10 so that the electron-side electro-luminescence material emits light. In this way, the number of excitons c moving to the electron transport layer 11 is decreased.

During the operation of the OLED device, holes a move from the anode 2 towards the electro-luminescence layer 7, and electrons b move from the cathode 12 towards the electro-luminescence layer 7. The holes a moving to the electro-luminescence layer 7 may move towards the electron transport layer 11, and the electrons b moving to the electro-luminescence layer 7 may move towards the hole transport layer 3. When the holes a move towards the electron transport layer 11, the holes a will pass through the electron-side exciton utilization layer 10. The electron-side exciton utilization layer 10 captures the holes a. The holes are combined with the electrons b moving from the cathode 12 towards the electro-luminescence layer 7 and passing through the electron-side exciton utilization layer 10 to form excitons c. Since the energy level of the electron-side electro-luminescence material in the electron-side exciton utilization layer 10 is lower than that of the material of the electron transport layer 11, the excitons c can excite the electron-side electro-luminescence material in the electron-side exciton utilization layer 10 so that the electron-side electro-luminescence material emits light. In this way, the number of holes a moving to the electron transport layer 11 is decreased, and the number of excitons c present in the electron transport layer 11 is thus decreased. Similarly, when the electrons b move towards the hole transport layer 3, the electrons b will pass through the hole-side exciton utilization layer 4. The hole-side exciton utilization layer 4 captures the electrons b. The electrons b are combined with the holes a moving from the anode 2 to the electro-luminescence layer 7 and passing through the hole-side exciton utilization layer 4 to form excitons c. Since the energy level of the hole-side electro-luminescence material in the hole-side exciton utilization layer 4 is lower than that of the material of the hole transport layer 3, the excitons c can excite the hole-side electro-luminescence material in the hole-side exciton utilization layer 4 so that the hole-side electro-luminescence material emits light. In this way, the number of electrons b moving to the hole transport layer 3 is decreased, and the number of excitons c present in the hole transport layer 3 is thus decreased.

It can be known from the above analysis that, during the operation of the OLED device provided by the embodiments of the present disclosure, excitons c moving from the electro-luminescence layer 7 towards the hole transport layer 3 will pass through the hole-side exciton utilization layer 4, and the hole-side exciton utilization layer 4 captures the excitons c moving from the electro-luminescence layer 7 towards the hole transport layer 3. The excitons c excite the hole-side electro-luminescence material so that the hole-side electro-luminescence material emits light. Meanwhile, electrons b moving from the electro-luminescence layer 7 to the hole transport layer 3 will also pass through the hole-side exciton utilization layer 4. The hole-side exciton utilization layer 4 captures the electrons b moving from the electro-luminescence layer 7 towards the hole transport layer 3, and the electrons b are combined with holes a transported in the hole-side exciton utilization layer 4 to form excitons c. Since the energy level of the hole-side electro-luminescence material is lower than that of the material of the hole transport layer 3, the excitons c can excite the hole-side electro-luminescence material so that the hole-side electro-luminescence material emits light. In this way, the number of excitons c or electrons b moving to the hole transport layer 3 is decreased, and the number of excitons c present in the hole transport layer 3 is thus decreased. Similarly, excitons c moving from the electro-luminescence layer 7 towards the electron transport layer 11 will pass through the electron-side exciton utilization layer 10, and the electron-side exciton utilization layer 10 captures the excitons c moving from the electro-luminescence layer 7 to the electron transport layer 11. Since the energy level of the electron-side electro-luminescence material is lower than that of the material of the electron transport layer 11, the excitons c can excite the electron-side electro-luminescence material so that the electron-side electro-luminescence material emits light. Meanwhile, holes a moving from the electro-luminescence layer 7 towards the electron transport layer 11 will also pass through the electron-side exciton utilization layer 10, and the electron-side exciton utilization layer 10 captures the holes a moving from the electro-luminescence layer 7 to the electron transport layer 11. The holes a are combined with the electrons b transported in the electron-side exciton utilization layer 10 to form excitons c for exciting the electron-side electro-luminescence material so that the electron-side electro-luminescence material emits light. In this way, the number of excitons c or electrons b moving to the electron transport layer 11 is decreased, and the number of excitons c present in the electron transport layer 11 is thus decreased. Therefore, during the operation of the OLED device provided by an embodiment of the present disclosure, since the hole-side exciton utilization layer 4 can capture excitons c or/and electrons b moving from the electro-luminescence layer 7 to the hole transport layer 3 and the electron-side exciton utilization layer 10 can capture excitons c or/and holes a moving from the electro-luminescence layer 7 to the electron transport layer 11, the number of excitons c present in the transport layers in the OLED device can be decreased, and the number of excitons c deactivated in a non-radiative transition heat transfer manner can also be decreased. In this way, the temperature within the OLED device is prevented from rising due to the presence of many excitons deactivated in the non-radiative transition heat transfer manner. Accordingly, the aging of the OLED device is slowed down, and the service life of the OLED device is prolonged.

In addition, during the operation of the OLED device provided by the embodiments of the present disclosure, the hole-side exciton utilization layer 4 can capture excitons c or/and electrons b moving from the electro-luminescence layer 7 to the hole transport layer 3. The excitons c captured by the hole-side exciton utilization layer 4 can excite the hole-side electro-luminescence material in the hole-side exciton utilization layer 4 so that the hole-side electro-luminescence material emits light. The excitons c formed by combining the electrons b captured by the hole-side exciton utilization layer 4 with the holes transported in the hole-side exciton utilization layer 4 can also excite the hole-side electro-luminescence material in the hole-side exciton utilization layer 4 so that the hole-side electro-luminescence material emits light. Similarly, the electron-side exciton utilization layer 10 can capture excitons c or/and holes a moving from the electro-luminescence layer 7 to the electron transport layer 11, the excitons c captured by the electron-side exciton utilization layer 10 can excite the electron-side electro-luminescence material in the electron-side exciton utilization layer 10 so that the electron-side electro-luminescence material emits light. The excitons c formed by combining the holes a captured by the electron-side exciton utilization layer 10 with the electrons b transported in the electron-side exciton utilization layer 10 can also excite the electron-side electro-luminescence material in the electron-side exciton utilization layer 10 so that the electron-side electro-luminescence material emits light. Therefore, in the OLED device provided by the embodiments of the present disclosure, by providing the hole-side exciton utilization layer 4 or/and the electron-side exciton utilization layer 10, the luminescence efficiency of the OLED device can be improved, and the electric energy can be saved.

In an embodiment of this disclosure, in the hole-side exciton utilization layer 4, the doping concentration of the hole-side electro-luminescence material can be about 0.5 wt % to 1 wt %. In practical applications, the doping concentration of the hole-side electro-luminescence material can be considered as a mass percentage of the hole-side electro-luminescence material in the material of the hole-side exciton utilization layer 4. For example, in the hole-side exciton utilization layer 4, the doping concentration of the hole-side electro-luminescence material can be 0.5 wt %, 0.8 wt %, 1 wt % or the like. Such an arrangement can avoid the hindering of the holes a when passing through the hole-side exciton utilization layer 4 due to a too high doping concentration of the hole-side electro-luminescence material, and avoid the performance degradation of the hole-side exciton utilization layer 4 in capturing excitons c and electrons b due to a too low doping concentration of the hole-side electro-luminescence material.

In an embodiment of this disclosure, in the electron-side exciton utilization layer 10, the doping concentration of the electron-side electro-luminescence material can be about 0.5 wt % to 1 wt %. In practical applications, the doping concentration of the electron-side electro-luminescence material can be considered as a mass percentage of the electron-side electro-luminescence material in the material of the electron-side exciton utilization layer 10. For example, in the electron-side exciton utilization layer 10, the doping concentration of the electron-side electro-luminescence material can be 0.5 wt %, 0.8 wt %, 1 wt % or the like. Such an arrangement can avoid the hindering of the electrons b when passing through the electron-side exciton utilization layer 10 due to a too high doping concentration of the electron-side electro-luminescence material, and avoid the performance degradation of the electron-side exciton utilization layer 10 in capturing excitons c and holes a due to a too low doping concentration of the electron-side electro-luminescence material.

In an embodiment of this disclosure, a distance between a surface of the hole-side exciton utilization layer 4 facing the electro-luminescence layer 7 and a surface of the electro-luminescence layer 7 facing the hole-side exciton utilization layer 4 is about 0 nm to 5 nm. Illustratively, when there is no any layered structure (for example, an auxiliary hole transport layer 5, an electron barrier layer 6 and the like) between the hole-side exciton utilization layer 4 and the electro-luminescence layer 7, the distance between the surface of the hole-side exciton utilization layer 4 facing the electro-luminescence layer 7 and the surface of the electro-luminescence layer 7 facing the hole-side exciton utilization layer 4 is 0 nm; and, when there are other layered structures between the hole-side exciton utilization layer 4 and the electro-luminescence layer 7 and the total thickness of the other layered structures is less than or equal to 5 nm, the distance between the surface of the hole-side exciton utilization layer 4 facing the electro-luminescence layer 7 and the surface of the electro-luminescence layer 7 facing the hole-side exciton utilization layer 4 is less than or equal to 5 nm. With such an arrangement, the hole-side exciton utilization layer 4 is close to the electro-luminescence layer 7, so that the hole-side exciton utilization layer 4 can capture more excitons c or/and electrons b. In this way, the number of excitons c or/and electrons b moving to the hole transport layer 3 is decreased, and the number of excitons c present in the hole transport layer 3 is further decreased.

In an embodiment of this disclosure, a distance between a surface of the electron-side exciton utilization layer 10 facing the electro-luminescence layer 7 and a surface of the electro-luminescence layer 7 facing the electron-side exciton utilization layer 10 is about 0 nm to 5 nm. Illustratively, when there is no any layered structure (for example, an auxiliary electron transport layer 9, a hole barrier layer 8 and the like) between the electron-side exciton utilization layer 10 and the electro-luminescence layer 7, the distance between the surface of the electron-side exciton utilization layer facing the electro-luminescence layer 7 and the surface of the electro-luminescence layer 7 facing the electron-side exciton utilization layer 10 is 0 nm; and, when there are other layered structures between the electron-side exciton utilization layer 10 and the electro-luminescence layer 7 and the total thickness of the other layered structures is less than or equal to 5 nm, the distance between the surface of the electron-side exciton utilization layer 10 facing the electro-luminescence layer 7 and the surface of the electro-luminescence layer 7 facing the electron-side exciton utilization layer 10 is less than or equal to 5 nm. With such an arrangement, the electron-side exciton utilization layer 10 is close to the electro-luminescence layer 7, so that the electron-side exciton utilization layer 10 can capture more excitons c or/and holes a. In this way, the number of excitons c or/and holes a moving to the electron transport layer 11 is decreased, and the number of excitons c present in the electron transport layer 11 is further decreased.

In an embodiment of this disclosure, the thickness of the hole-side exciton utilization layer 4 may be about 3 nm to 5 nm. For example, the thickness of the hole-side exciton utilization layer 4 may be 3 nm, 4 nm or 5 nm, in order to avoid the hindering of the holes a when being transported in the hole-side exciton utilization layer 4 due to a too large thickness of the hole-side exciton utilization layer 4, and avoid the performance degradation of the hole-side exciton utilization layer 4 in capturing excitons c or/and electrons b due to a too small thickness of the hole-side exciton utilization layer 4.

In an embodiment of this disclosure, the thickness of the electron-side exciton utilization layer 10 may be about 3 nm to 5 nm. For example, the thickness of the electron-side exciton utilization layer 10 may be 3 nm, 4 nm or 5 nm, in order to avoid the hindering of the electrons b when being transported in the electron-side exciton utilization layer 10 due to a too large thickness of the electron-side exciton utilization layer 10, and avoid the performance degradation of the electron-side exciton utilization layer 10 in capturing excitons c or/and holes a due to a too small thickness of the electron-side exciton utilization layer 10.

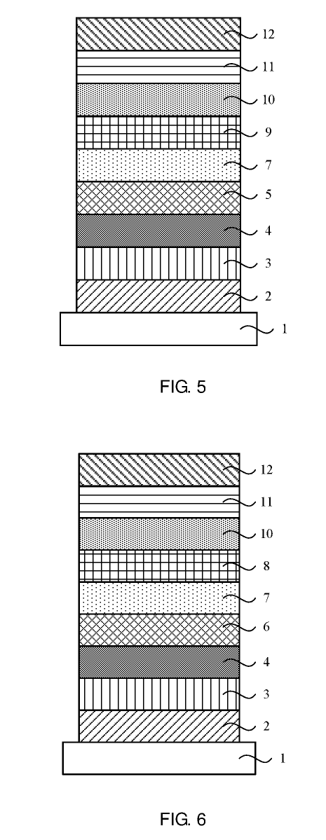

Referring to FIG. 5, in an embodiment of this disclosure, the OLED device further includes an auxiliary hole transport layer 5 for facilitating the transport of holes a to the electro-luminescence layer 7, and the auxiliary hole transport layer 5 can be located between the hole-side exciton utilization layer 4 and the electro-luminescence layer 7. In this case, the material of the auxiliary hole transport layer 5 can be the same as the material of the hole transport layer 3, that is, it is equivalent that two hole transport layers are provided in the OLED device and a hole-side exciton utilization layer 4 is provided between the two hole transport layers.

Still referring to FIG. 5, in an embodiment of this disclosure, the OLED device provided by the embodiments of the present disclosure further includes an auxiliary electron transport layer 9 for facilitating the transport of electrons b to the electro-luminescence layer 7, and the auxiliary electron transport layer 9 can be located between the electron-side exciton utilization layer 10 and the electro-luminescence layer 7. In this case, the material of the auxiliary electron transport layer 9 can be the same as the material of the electron transport layer 11, that is, it is equivalent that two electron transport layers are provided in the OLED device and a hole-side exciton utilization layer 4 is provided between the two electron transport layer.

Still referring to FIG. 5, in an embodiment of this disclosure, when the OLED device further includes an auxiliary hole transport layer 5 and an auxiliary electron transport layer 9, the material of the auxiliary hole transport layer 5 is the same as the material of the hole transport layer 3 and the material of the auxiliary electron transport layer 9 is the same as the material of the electron transport layer 11, the host material of the hole-side exciton utilization layer 4 can be the same as the material of the hole transport layer 3, and the host material of the electron-side exciton utilization layer 10 can be the same as the material of the electron transport layer 11.

Referring to FIG. 6, in an embodiment of this disclosure, the OLED device further includes an electron barrier layer 6 which is located between the hole-side exciton utilization layer 4 and the electro-luminescence layer 7 or located between the hole transport layer 3 and the hole-side exciton utilization layer 4, and the energy level of the hole-side electro-luminescence material is lower than that of material of the electron barrier layer 6. By providing the electron barrier layer 6, the number of electrons b moving from the electro-luminescence layer 7 to the hole transport layer 3 can be decreased, and the number of excitons c present in the hole transport layer 3 can be further decreased.

Still referring to FIG. 6, in an embodiment of this disclosure, the OLED device further includes a hole barrier layer 8 which is located between the electron-side exciton utilization layer 10 and the electro-luminescence layer 7 or located between the electron transport layer 11 and the hole-side exciton utilization layer 4, and the energy level of the electron-side electro-luminescence material is lower than that of material of the hole barrier layer 8. By providing the hole barrier layer 8, the number of holes a moving from the electro-luminescence layer 7 to the electron transport layer 11 can be decreased, and the number of excitons c present in the electron transport layer 11 can be further decreased.

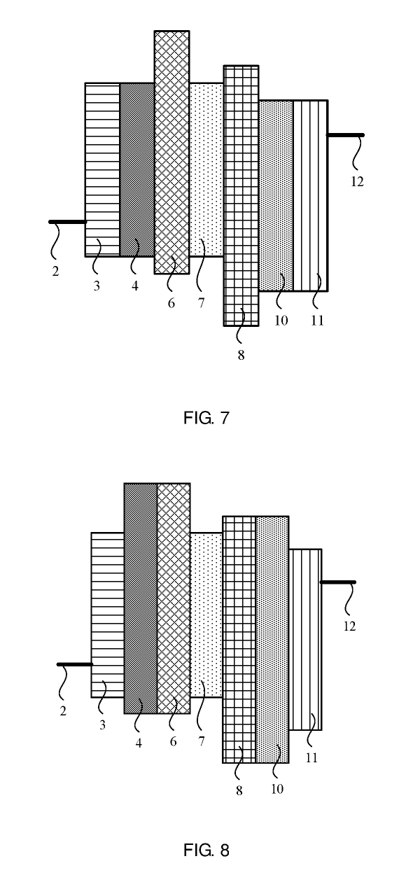

In an embodiment of the present disclosure, the hole-side exciton utilization layer 4 includes hole-side host material and hole-side electro-luminescence material doped in the hole-side host material, and the hole-side host material in the hole-side exciton utilization layer 4 can be the same as the material of the electron barrier layer 6. In this case, referring to FIG. 8, the hole-side exciton utilization layer 4 can be located between the hole transport layer 3 and the electron barrier layer 6. Of course, in practical applications, the hole-side exciton utilization layer 4 can also be located between the electron barrier layer 6 and the electro-luminescence layer 7. The hole-side host material in the hole-side exciton utilization layer 4 can also be the same as the material of the hole transport layer 3. In this case, referring to FIG. 7, the hole-side exciton utilization layer 4 may be located between the hole transport layer 3 and the electron barrier layer 6. Since the hole-side host material is the same as the material of the hole transport layer 3 or the material of the electron barrier layer 6, the introduction of new material into the OLED device can be avoided, and the cost can be thus saved.

The electron-side exciton utilization layer 10 includes electron-side host material and electron-side electro-luminescence material doped in the electron-side host material, and the electron-side host material in the electron-side exciton utilization layer 10 can be the same as the material of the hole barrier layer 8. In this case, referring to FIG. 8, the electron-side exciton utilization layer 10 can be located between the electron transport layer 11 and the hole barrier layer 8. Of course, in practical applications, the electron-side exciton utilization layer 10 can also be located between the hole barrier layer 8 and the electro-luminescence layer 7. The electron-side host material in the electron-side exciton utilization layer 10 can also be the same as the material of the electron transport layer 11. In this case, referring to FIG. 7, the electron-side exciton utilization layer 10 is preferably located between the electron transport layer 11 and the hole barrier layer 8. Since the electron-side host material is the same as the material of the electron transport layer 11 or the material of the hole barrier layer 8, the introduction of new material into the OLED device can be avoided, and the cost can be thus saved.

In an embodiment of the present disclosure, the OLED device is a monochromatic OLED device, for example, a red OLED device, a green OLED device or a blue OLED device. The hole-side electro-luminescence material in the hole-side exciton utilization layer 4 is the same as the material of the electro-luminescence layer 7. The electron-side electro-luminescence material in the electron-side exciton utilization layer 10 is the same as the material of the electro-luminescence layer 7. For example, when the OLED device is a monochromatic OLED device and the electro-luminescence layer 7 of the OLED device is an electro-phosphorescence layer, both the hole-side electro-luminescence material and the electron-side electro-luminescence material are electro-phosphorescence material the same as the material of the electro-phosphorescence layer; or, when the OLED device is a monochromatic OLED device and the electro-luminescence layer 7 of the OLED device is an electro-fluorescence layer, both the hole-side electro-luminescence material and the electron-side electro-luminescence material are electro-fluorescence material the same as the material of the electro-fluorescence layer, so as to improve the color purity of light emitted by the OLED device.

In an embodiment of the present disclosure, when the OLED device provided by the embodiments of the present disclosure is a white OLED device or a non-monochromatic OLED device, the hole-side electro-luminescence material in the hole-side exciton utilization layer 4 can be the same as or different from the material of the electro-luminescence layer 7, and the electron-side electro-luminescence material in the electron-side exciton utilization layer 10 can be the same as or different from the material of the electro-luminescence layer 7. For example, in the OLED device, when the electro-luminescence layer 7 is an electro-phosphorescence layer, the hole-side electro-luminescence material can be electro-phosphorescence material or other electro-luminescence material such as electro-fluorescence material, and the electron-side electro-luminescence material can be electro-phosphorescence material or other electro-luminescence material such as electro-fluorescence material; or, in the OLED device, when the electro-luminescence layer 7 is an electro-fluorescence layer, the hole-side electro-luminescence material can be electro-fluorescence material or other electro-luminescence material such as electro-phosphorescence material, and the electron-side electro-luminescence material can be electro-fluorescence material or other electro-luminescence material such as electro-phosphorescence material.

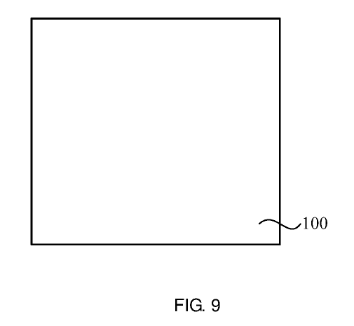

As shown in FIG. 9, an embodiment of the present disclosure further provides an OLED display device 100, including the OLED device provided in the foregoing embodiments.

The OLED display device has the same advantages as the OLED device, and the advantages will not be repeated here.

In the descriptions of the implementations, specific features, structures, materials or characteristics can be combined appropriately in any one or more embodiments or examples.

The foregoing descriptions merely show specific implementations of the present disclosure, and the protection scope of the present disclosure is not limited thereto. Any person of skill in the art can readily conceive of variations or replacements within the technical scope disclosed by the embodiments of the present disclosure, and these variations or replacements shall fall into the protection scope of the present disclosure. Accordingly, the protection scope of the present disclosure shall be subject to the protection scope of the claims.

What is claimed is:

1. An organic Light Emitting Diode OLED device, comprising an anode, a hole transport layer, an electro-luminescence layer, an electron transport layer and a cathode, which are superposed successively,
wherein a hole-side exciton utilization layer for allowing holes to freely pass therethrough is provided between the hole transport layer and the electro-luminescence layer, and an electron-side exciton utilization layer for allowing electrons to freely pass therethrough is provided between the electron transport layer and the electro-luminescence layer; hole-side electro-luminescence material is doped in the hole-side exciton utilization layer, and the energy level of the hole-side electro-luminescence material is lower than that of material of the hole transport layer; and electron-side electro-luminescence material is doped in the electron-side exciton utilization layer, and the energy level of the electron-side electro-luminescence material is lower than that of material of the electron transport layer.

2. The OLED device according to claim 1, wherein, in the hole-side exciton utilization layer, the doping concentration of the hole-side electro-luminescence material is about 0.5 wt % to 1 wt %; and
in the electron-side exciton utilization layer, the doping concentration of the electron-side electro-luminescence material is about 0.5 wt % to 1 wt %.

3. The OLED device according to claim 1, wherein
a distance between a surface of the hole-side exciton utilization layer facing the electro-luminescence layer and a surface of the electro-luminescence layer facing the hole-side exciton utilization layer is about 0 nm to 5 nm; and,
a distance between a surface of the electron-side exciton utilization layer facing the electro-luminescence layer and a surface of the electro-luminescence layer facing the electron-side exciton utilization layer is about 0 nm to 5 nm.

4. The OLED device according to claim 1, wherein that the thickness of the hole-side exciton utilization layer is about 3 nm to 5 nm, and the thickness of the electron-side excitation utilization layer is about 3 nm to 5 nm.

5. The OLED device according to claim 1, wherein
the OLED device further comprises an auxiliary hole transport layer for facilitating transportation of holes to the electro-luminescence layer, and the auxiliary hole transport layer is located between the hole-side exciton utilization layer and the electro-luminescence layer; and
the OLED device further comprises an auxiliary electron transport layer for facilitating transportation of electrons to the electro-luminescence layer, and the auxiliary electron transport layer is located between the electron-side exciton utilization layer and the electro-luminescence layer.

6. The OLED device according to claim 1, wherein
the OLED device further comprises an electron barrier layer which is located between the hole-side exciton utilization layer and the electro-luminescence layer or located between the hole transport layer and the hole-side exciton utilization layer, and the energy level of the hole-side electro-luminescence material is lower than that of material of the electron barrier layer; and
the OLED device further comprises a hole barrier layer which is located between the electron-side exciton utilization layer and the electro-luminescence layer or located between the electron transport layer and the hole-side exciton utilization layer, and the energy level of the electron-side electro-luminescence material is lower than that of material of the hole barrier layer.

7. The OLED device according to claim 6, wherein the hole-side exciton utilization layer comprises hole-side host material in which the hole-side electro-luminescence material is doped, and the hole-side host material is the same as material of the electron barrier layer; and
the electron-side exciton utilization layer comprises electron-side host material in which the electron-side electro-luminescence material is doped, and the electron-side host material is the same as material of the hole barrier layer.

8. The OLED device according to claim 6, wherein the hole-side exciton utilization layer comprises hole-side host material in which the hole-side electro-luminescence material is doped, and the hole-side host material is the same as material of the hole transport layer; and
the electron-side exciton utilization layer comprises electron-side host material in which the electron-side electro-luminescence material is doped, and the electron-side host material is the same as material of the electron transport layer.

9. The OLED device according to claim 1, wherein the hole-side electro-luminescence material is the same or different with material of the electro-luminescence layer, and the electron-side electro-luminescence material is the same or different with material of the electro-luminescence layer.

10. An OLED display device, comprising the OLED device according to claim 1.

11. An organic Light Emitting Diode OLED device, comprising an anode, a hole transport layer, an electro-luminescence layer, an electron transport layer and a cathode, which are superposed successively,
wherein a hole-side exciton utilization layer for allowing holes to freely pass therethrough is provided between the hole transport layer and the electro-luminescence layer, or an electron-side exciton utilization layer for allowing electrons to freely pass therethrough is provided between the electron transport layer and the electro-luminescence layer; hole-side electro-luminescence material is doped in the hole-side exciton utilization layer, and the energy level of the hole-side electro-luminescence material is lower than that of material of the hole transport layer; and electron-side electro-luminescence material is doped in the electron-side exciton utilization layer, and the energy level of the electron-side electro-luminescence material is lower than that of material of the electron transport layer.

12. The OLED device according to claim 11, wherein, in the hole-side exciton utilization layer, the doping concentration of the hole-side electro-luminescence material is about 0.5 wt % to 1 wt %; and
in the electron-side exciton utilization layer, the doping concentration of the electron-side electro-luminescence material is about 0.5 wt % to 1 wt %.

13. The OLED device according to claim 11, wherein
a distance between a surface of the hole-side exciton utilization layer facing the electro-luminescence layer and a surface of the electro-luminescence layer facing the hole-side exciton utilization layer is about 0 nm to 5 nm; and,
a distance between a surface of the electron-side exciton utilization layer facing the electro-luminescence layer and a surface of the electro-luminescence layer facing the electron-side exciton utilization layer is about 0 nm to 5 nm.

14. The OLED device according to claim 11, wherein that the thickness of the hole-side exciton utilization layer is about 3 nm to 5 nm, and the thickness of the electron-side excitation utilization layer is about 3 nm to 5 nm.

15. The OLED device according to claim 11, wherein
the OLED device further comprises an auxiliary hole transport layer for facilitating transportation of holes to the electro-luminescence layer, and the auxiliary hole transport layer is located between the hole-side exciton utilization layer and the electro-luminescence layer; and
the OLED device further comprises an auxiliary electron transport layer for facilitating transportation of electrons to the electro-luminescence layer, and the auxiliary electron transport layer is located between the electron-side exciton utilization layer and the electro-luminescence layer.

16. The OLED device according to claim 11, wherein
the OLED device further comprises an electron barrier layer which is located between the hole-side exciton utilization layer and the electro-luminescence layer or located between the hole transport layer and the hole-side exciton utilization layer, and the energy level of the hole-side electro-luminescence material is lower than that of material of the electron barrier layer; and
the OLED device further comprises a hole barrier layer which is located between the electron-side exciton utilization layer and the electro-luminescence layer or located between the electron transport layer and the hole-side exciton utilization layer, and the energy level of the electron-side electro-luminescence material is lower than that of material of the hole barrier layer.

17. The OLED device according to claim 16, wherein the hole-side exciton utilization layer comprises hole-side host material in which the hole-side electro-luminescence material is doped, and the hole-side host material is the same as material of the electron barrier layer; and
the electron-side exciton utilization layer comprises electron-side host material in which the electron-side electro-luminescence material is doped, and the electron-side host material is the same as material of the hole barrier layer.

18. The OLED device according to claim 16, wherein the hole-side exciton utilization layer comprises hole-side host material in which the hole-side electro-luminescence material is doped, and the hole-side host material is the same as material of the hole transport layer; and
the electron-side exciton utilization layer comprises electron-side host material in which the electron-side electro-luminescence material is doped, and the electron-side host material is the same as material of the electron transport layer.

19. The OLED device according to claim 11, wherein the hole-side electro-luminescence material is the same or different with material of the electro-luminescence layer, and the electron-side electro-luminescence material is the same or different with material of the electro-luminescence layer.

20. An OLED display device, comprising the OLED device according to claim 11.
